(19) United States
(12) Patent Application Publication
(10) Pub. No.: US 2020/0058533 A1
(43) Pub. Date: Feb. 20, 2020

(54) METHOD FOR TRANSFERRING MASSIVE MICRO-LED AND MICRO-LED SUBSTRATE

(71) Applicants: FUZHOU BOE OPTOELECTRONICS TECHNOLOGY CO., LTD., Fuzhou (CN); BOE TECHNOLOGY GROUP CO., LTD., Beijing (CN)

(72) Inventors: Zhenyou ZOU, Beijing (CN); Liangliang LI, Beijing (CN); Yazhou HUO, Beijing (CN); Fanqing MENG, Beijing (CN); Rong WU, Beijing (CN); Wenxing XI, Beijing (CN); Kaibin KONG, Beijing (CN)

(73) Assignees: FUZHOU BOE OPTOELECTRONICS TECHNOLOGY CO., LTD., Fuzhou (CN); BOE TECHNOLOGY GROUP CO., LTD., Beijing (CN)

(21) Appl. No.: 16/392,961

(22) Filed: Apr. 24, 2019

(30) Foreign Application Priority Data
Aug. 17, 2018 (CN) 201810939699.6

(51) Int. Cl. H01L 21/677; H01L 33/00; H01L 33/62; H01L 27/15

(52) U.S. Cl. CPC H01L 21/67739; H01L 27/156; H01L 33/62; H01L 33/005

(57) ABSTRACT

A method for transferring massive Micro-LED includes: providing a transfer plate including a base substrate, an insulation film on the base substrate and provided with recesses, and first metal bonding pads in the recesses; providing Micro-LED grains each provided with a second bonding metal at a backside of the Micro-LED gain; forming solder on the first metal bonding pad or the second metal bonding pad; placing the transfer plate and the Micro-LED gains into a chamber which contains solvent and has a temperature higher than a melting point of the solder, vibrating the chamber to enable the Micro-LED gains to fall into the recesses, thereby enabling the second metal bonding pads of the Micro-LED gains fallen in the recesses to be in contact with the first metal bonding pads in the recesses through the solder; and cooling down the transfer plate, thereby solidifying the solder and forming a Micro-LED substrate.

### CROSS-REFERENCE TO RELATED APPLICATION

This application claims priority to Chinese Patent Application No. 201810939699.6 filed on Aug. 17, 2018, which is incorporated herein by reference in its entirety.

### TECHNICAL FIELD

The present disclosure relates to the field of Micro-LED technologies, and in particular to a method for transferring massive Micro-LED and a Micro-LED substrate.

### BACKGROUND

Micro light emitting diodes (Micro-LEDs) are a new generation display technology that provides higher brightness, better luminous efficiency and lower power consumption than the existing organic light emitting diode (OLED) technology. According to the Micro-LED technology, the structure of an LED is thinned, miniaturized and arrayed, and its size is only around 1˜10 μm. The greatest advantage of the Micro-LED comes from the micrometer-level spacing. Each pixel can be addressed and controlled, can be driven to emit light at a single point, and has a long service life and wide application. However, the bottleneck limiting the development of the Micro-LED display technology mainly includes massive transfer technology. The massive transfer technology is about how to transfer massive micro-scale Micro-LED grains to a large-size transfer plate, and is an important technology for the mass production of Micro-LED products. How to ensure the low cost and high yield of the massive transfer technology is the main technical problem at present.

### SUMMARY

One embodiment of the present disclosure provides a method for transferring massive Micro-LED, including: providing a transfer plate; wherein the transfer plate includes a base substrate, an insulation film on the base substrate and a plurality of first metal bonding pads on the base substrate, the insulation film is provided with a plurality of recesses for accommodating Micro-LED grains, and the first metal bonding pad is in the recess; providing a plurality of Micro-LED grains; wherein the Micro-LED gain is provided with a second bonding metal at a backside of the Micro-LED gain, and the backside of the Micro-LED gain and a light emitting side of the Micro-LED gain are two opposite sides of the Micro-LED gain; forming solder on the first metal bonding pad of the transfer plate or the second metal bonding pad of the Micro-LED gain; placing the transfer plate and the Micro-LED gains into a chamber which contains solvent, vibrating the chamber to enable the Micro-LED gains to fall into the recesses of the transfer plate, thereby enabling the second metal bonding pads of the Micro-LED gains fallen in the recesses to be in contact with the first metal bonding pads in the recesses through the solder; wherein a temperature in the chamber is higher than a melting point of the solder; and, cooling down the transfer plate, thereby solidifying the solder and then forming a Micro-LED substrate.

In one embodiment, the cooling down the transfer plate includes: removing the solvent from the chamber and cooling down the chamber; or, removing the transfer plate from the chamber and cooling down the transfer plate.

In one embodiment, the solvent is an organic solvent.

In one embodiment, a density of the organic solvent is less than a preset density threshold.

In one embodiment, the forming solder on the first metal bonding pad of the transfer plate or the second metal bonding pad of the Micro-LED gain, includes: placing the transfer plate or the Micro-LED gains into liquid-state solder, thereby forming the solder on the first metal bonding pads of the transfer plate or the second metal bonding pads of the Micro-LED gains.

In one embodiment, the solder is a eutectic solder.

In one embodiment, an electromagnet base station is provided below the chamber; the vibrating the chamber includes: energizing an electromagnet of the electromagnet base station corresponding to a specified region of the transfer plate, and controlling the electromagnet base station to vibrate, thereby vibrating the chamber and then enabling the Micro-LED grains to fall into recesses corresponding to the specified region under action of vibration and electromagnetic force.

In one embodiment, the Micro-LED grains include N types of Micro-LED grains, wherein N is a positive integer greater than or equal to 2; light rays emitted from the Micro-LED grains of different types have different colors; the placing the transfer plate and the Micro-LED gains into a chamber which contains solvent, vibrating the chamber, includes: placing the transfer plate into the chamber; and for each of the N types of the Micro-LED grains, performing following operations sequentially: putting one type of the Micro-LED grains into the chamber, wherein the Micro-LED grains put into the chamber are corresponding to the recesses in the specified region of the transfer plate; and energizing the electromagnet of the electromagnet base station corresponding to the specified region of the transfer plate and controlling the electromagnet base station to vibrate, thereby vibrating the chamber and then enabling the Micro-LED grains put into the chamber to fall into recesses corresponding to the specified region under action of vibration and electromagnetic force.

In one embodiment, the Micro-LED grains of different types have different shapes; and the recesses have N shapes which are corresponding to the N types of Micro-LED grains in a one-to-one manner.

In one embodiment, the recess of each shape matches only the Micro-LED grain of the corresponding type.

In one embodiment, the Micro-LED grains include 3 types of Micro-LED grains, which include red Micro-LED grains for emitting red light, green Micro-LED grains for emitting green light and blue Micro-LED grains for emitting blue light.

In one embodiment, the providing a transfer plate includes: providing a base substrate; forming a metal film on the base substrate; patterning the metal film, thereby forming a plurality of first metal bonding pads; forming an insulation film on the base substrate; patterning the insulation film, thereby forming a plurality of recesses in the insulation film. One of the first metal bonding pads is in one of the recesses.

In one embodiment, the insulation film is an organic film or a passivation film.

In one embodiment, the providing a plurality of Micro-LED grains includes: providing a Micro-LED wafer; forming a metal layer on a backside of the Micro-LED wafer; cutting the Micro-LED wafer to form a plurality of Micro-LED grains; wherein one of the second metal bonding pads is provided at the backside of one Micro-LED grain.

In one embodiment, before the cutting the Micro-LED wafer to form a plurality of Micro-LED grains, the method further includes: patterning the metal layer, thereby forming a plurality of second metal bonding pads.

One embodiment of the present disclosure provides a Micro-LED substrate that includes: a base substrate; an insulation film on the base substrate and provided with a plurality of recesses; a plurality of first metal bonding pads on the base substrate and in the plurality of recesses; a plurality of Micro-LED grains in the plurality of recesses; wherein the Micro-LED gain is provided with a second bonding metal at a backside of the Micro-LED gain, the backside of the Micro-LED gain and a light emitting side of the Micro-LED gain are two opposite sides of the Micro-LED gain. The first metal bonding pad is welded to the second metal bonding pad via a solder.

In one embodiment, the first metal bonding pads are in the recesses in a one-to-one manner.

In one embodiment, the first metal bonding pads are directly formed on the base substrate.

In one embodiment, the Micro-LED grains include N types of Micro-LED grains, where N is a positive integer greater than or equal to 2; light rays emitted from the Micro-LED grains of different types have different colors; the Micro-LED grains of different types have different shapes; the recesses have N shapes which are corresponding to the N types of Micro-LED grains in a one-to-one manner.

In one embodiment, in a direction perpendicular to the base substrate, a thickness of the insulation film is equal to a sum of a thickness of the first metal bonding pad, a thickness of the second metal bonding pad, a thickness of the solder and a thickness of the Micro-LED grain.

### BRIEF DESCRIPTION OF THE DRAWINGS

In order to illustrate technical solutions according to embodiments of the present disclosure more clearly, drawings to be used in the description of the embodiments will be described briefly hereinafter. Apparently, the drawings described hereinafter are only some embodiments of the present disclosure, and other drawings may be obtained by those skilled in the art according to those drawings without creative work.

FIG. 1 is a flow chart of a method for transferring massive Micro-LED according to an embodiment of the present disclosure;

FIG. 2 is a schematic view of a process for manufacturing a Micro-LED substrate according to an embodiment of the present disclosure;

FIG. 3 is a flow chart of a method for preparing Micro-LED grains according to an embodiment of the present disclosure;

FIG. 4 is a schematic view of a Micro-LED substrate according to an embodiment of the present disclosure;

FIG. 5 is a schematic view of assembling Micro-LED grains to a transfer plate according to an embodiment of the present disclosure; and

FIG. 6 is a schematic view of a Micro-LED substrate according to an embodiment of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments are merely a part of, rather than all of, the embodiments of the present disclosure, and based on these embodiments, a person skilled in the art may obtain the other embodiments, which also fall within the scope of the present disclosure.

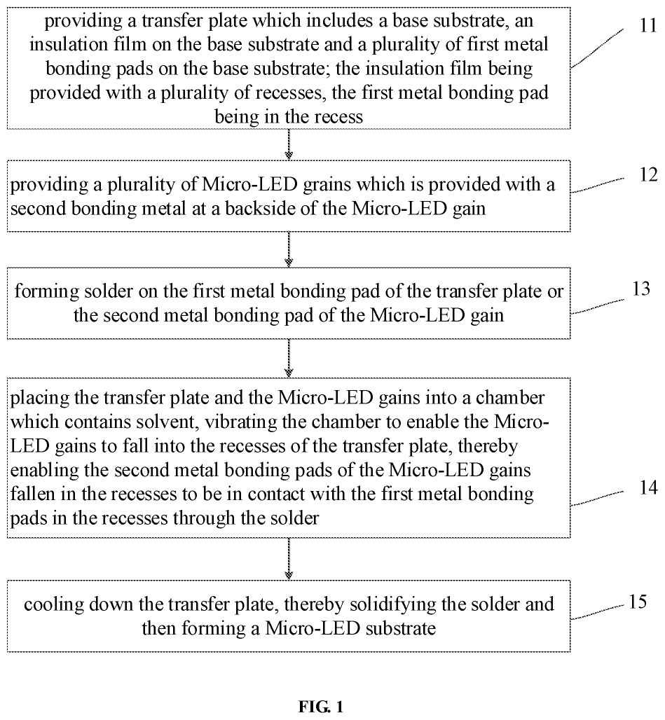

FIG. 1 is a flow chart of a method for transferring massive Micro-LED according to an embodiment of the present disclosure. Referring to FIG. 1, the method includes the following steps 11 to 15.

The step 11 is to provide a transfer plate. The transfer plate includes a base substrate, an insulation film on the base substrate and a plurality of first metal bonding pads on the base substrate. The insulation film is provided with a plurality of recesses for accommodating Micro-LED grains. The first metal bonding pad is in the recess.

The step 12 is to provide a plurality of Micro-LED grains. The Micro-LED gain is provided with a second bonding metal at a backside of the Micro-LED gain. The backside and a light emitting side of the Micro-LED gain are two opposite sides of the Micro-LED gain.

The step 13 is to form solder on the first metal bonding pad of the transfer plate or the second metal bonding pad of the Micro-LED gain.

The step 14 is to place the transfer plate and the Micro-LED gains into a chamber which contains solvent, vibrate the chamber to enable the Micro-LED gains to fall into the recesses of the transfer plate, thereby enabling the second metal bonding pads of the Micro-LED gains fallen in the recesses to be in contact with the first metal bonding pads in the recesses through the solder. The temperature in the chamber is higher than a melting point of the solder, thereby keeping the solder in liquid state. This step completes assembling of the Micro-LED gains to the transfer plate.

The step 15 is to cool down the transfer plate, thereby solidifying the solder and then forming a Micro-LED substrate.

In one embodiment of the present disclosure, the Micro-LED gains are transferred to the transfer plate through the low-temperature welding technology and the vibration assembly technology. The low-temperature welding technology can avoid the influence of high-temperature welding on the Micro-LED grains, thereby improving production yield with lower cost. The vibration assembly technology is simple and effective, can further reduce production costs. Meanwhile, since the chamber contains the solvent, the solvent can avoid collision of the Micro-LED grains with the transfer plate when the Micro-LED grains are placed into the chamber, thereby further improving production yield.

In some embodiments, the step of cooling down the transfer plate, thereby solidifying the solder, includes: removing the solvent from the chamber and cooling down the chamber.

Specifically, the step of removing the solvent from the chamber may include: evacuating the solvent in the chamber, or releasing the solvent through a valve or the like provided on the chamber. The step of cooling down the chamber may include: lowering the temperature in the chamber below the melting point of the solder, thereby solidifying the solder in liquid state.

In some embodiments, the step of cooling down the transfer plate, thereby solidifying the solder, includes: removing the transfer plate from the chamber and cooling down the transfer plate.

In one embodiment of the present disclosure, optionally, the solvent is an organic solvent. The organic solvent is stable and does not react with the micro-LED grains and components on the transfer plate.

In one embodiment of the present disclosure, optionally, the density of the organic solvent is less than a preset density threshold, thereby enabling the micro-LED grains to easily move with less flow resistance. In some embodiments of the present disclosure, in order to reduce the buoyancy of the micro-LED grains, the density of the organic solvent may be less than the density of the micro-LED grains. For example, the density of the organic solvent may be less than ⅔ of the density of the micro-LED grains, in other words, the preset density threshold may be equal to ⅔ of the density of the micro-LED grains.

An approach for forming the transfer plate is described hereinafter.

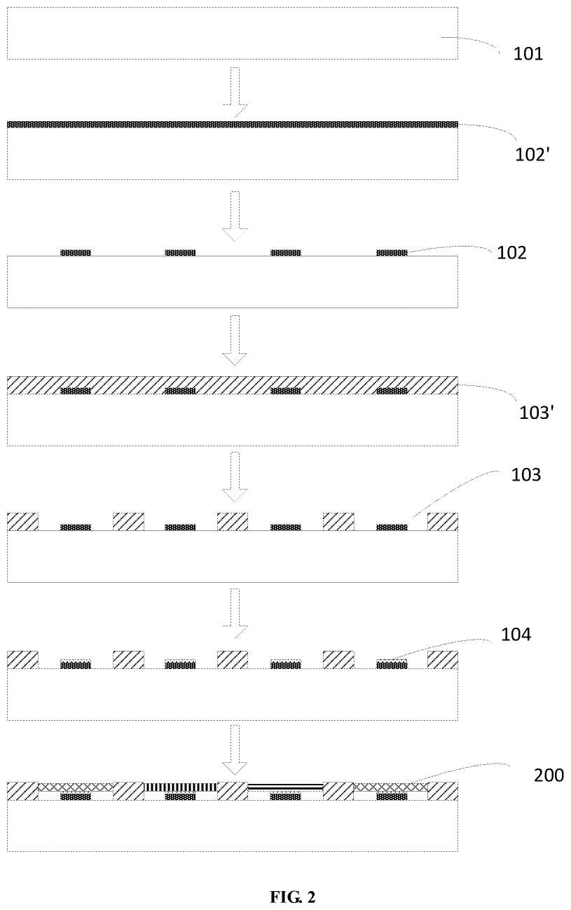

Referring to FIG. 2, an approach for forming the transfer plate according to an embodiment of the present disclosure may include following steps 111 to 115.

The step 111 is to provide a base substrate 101.

In one embodiment, optionally, the base substrate 101 may be a glass substrate or other types of substrates.

The step 112 is to form a metal film 102′ on the base substrate.

In one embodiment, optionally, the metal film 102′ may be made of materials such as Al or Cu.

The step 113 is to pattern the metal film 102′ to form a plurality of first metal bonding pads 102.

In one embodiment, optionally, the metal film 102′ may be patterned through a photolithography process, thereby forming a plurality of first metal bonding pads 102. The photolithography process may include steps such as coating photoresist, exposing, developing and etching.

The step 114 is to form an insulation film 103′ on the base substrate 101.

In one embodiment, optionally, the insulation film may be an organic film or a passivation (PVX) film. The passivation is usually made of SiNx. Since there is a certain requirement for the depth of the recesses, there is a certain requirement for the thickness of the insulation film. When the insulation film is an organic film, the organic film, the thickness of the organic film may be large and then the insulation film is easy to be prepared.

The step 115 is to pattern the insulation film 103′, thereby forming a plurality of recesses 103 in the insulation film 103.

The recesses 103 are used for accommodating Micro-LED grains. One of the first metal bonding pads 102 is in one of the recesses 103. Each recess 103 is used for accommodating one Micro-LED grain. It should be understood that the shape of each recess 103 has a shape matching the shape of one to-be-accommodated Micro-LED grain.

In one embodiment, optionally, the insulation film 103′ may be patterned through a photolithography process, thereby forming a plurality of recesses 103 in the insulation film 103′ at positions corresponding to the first metal bonding pads 102.

An approach for forming the Micro-LED grains is described hereinafter.

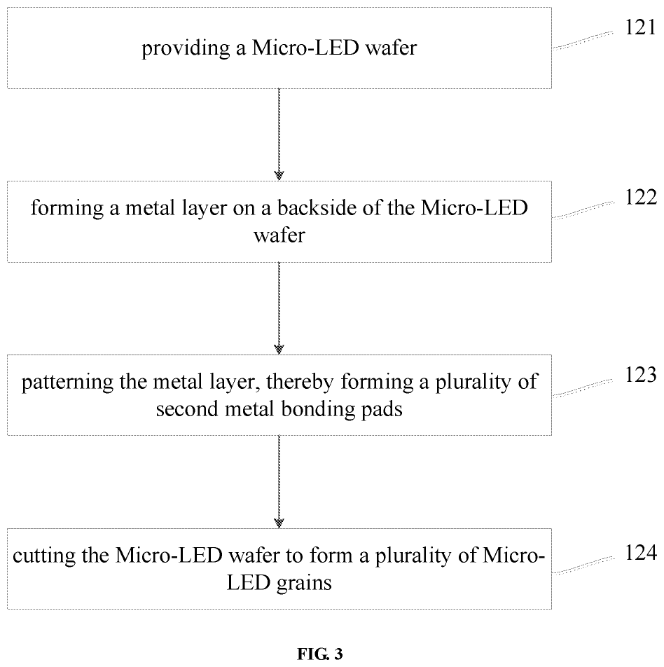

FIG. 3 is a flow chart of a method for preparing Micro-LED grains according to an embodiment of the present disclosure. Referring to FIG. 3, the method includes the following steps 121 to 123.

The step 121 is to provide a Micro-LED wafer.

The step 122 is to form a metal layer on a backside of the Micro-LED wafer.

The backside of the Micro-LED gain and a light emitting side of the Micro-LED gain are two opposite sides of the Micro-LED gain.

In one embodiment, optionally, the metal layer may be made of materials such as Al or Cu.

The step 123 is to pattern the metal layer, thereby forming a plurality of second metal bonding pads.

In one embodiment, optionally, the metal layer may be patterned through a photolithography process, thereby forming a plurality of second metal bonding pads. The photolithography process may include steps such as coating photoresist, exposing with masks, developing, etching and stripping.

The step 124 is to cut the Micro-LED wafer to form a plurality of Micro-LED grains. One second metal bonding pad is provided at the backside of each Micro-LED grain.

In some embodiments of the present disclosure, the step 123 may be omitted, i.e., not to pattern the metal layer, instead, to directly cut the Micro-LED wafer provided with the metal layer.

In one embodiment, optionally, the Micro-LED grains include N types of Micro-LED grains, where N is a positive integer greater than or equal to 2. Light rays emitted from the Micro-LED grains of different types have different colors. In one embodiment, N types of Micro-LED grains may be adopted to form a Micro-LED substrate capable of realizing color display.

In one embodiment, optionally, the Micro-LED grains include 3 types of Micro-LED grains, which include red Micro-LED grains for emitting red light, green Micro-LED grains for emitting green light and blue Micro-LED grains for emitting blue light.

In one embodiment, optionally, the Micro-LED grains of different types have different shapes. Meanwhile, the recesses have N shapes which are corresponding to the N types of Micro-LED grains in a one-to-one manner. Since the Micro-LED grains of different types have different shapes and the corresponding recesses have different shapes, when assembling the Micro-LED grains, each of the Micro-LED grains can only be embedded in one recess of corresponding shape, thereby improving yield.

In one embodiment, optionally, the recess of each shape can only be adapted to the corresponding type of Micro-LED grain. In other words, the recess of one type of shape can only accommodate one type of Micro-LED grain, and each Micro-LED grain cannot fall into one recess which is not corresponding to the position of each Micro-LED grain, thereby further improving yield.

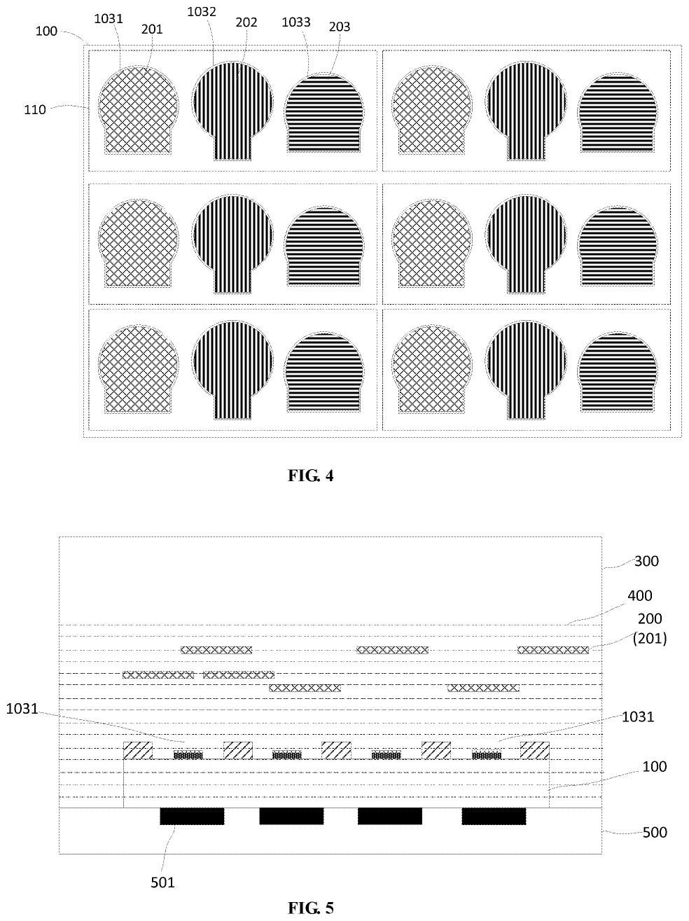

FIG. 4 is a schematic view of a Micro-LED substrate according to an embodiment of the present disclosure. Referring to FIG. 4, the Micro-LED substrate includes a plurality of pixels 110. Each pixel 110 includes a red Micro-LED grain 201, a green Micro-LED grain 202 and a blue Micro-LED grain 203. Shapes of the red Micro-LED grain 201, the green Micro-LED grain 202 and the blue Micro-LED grain 203 are different from each other. Meanwhile, a first recess 1031 for accommodating the red Micro-LED grain 201, a second recess 1032 for accommodating the green Micro-LED grain 202, and a third recess 1033 for accommodating the blue Micro-LED grain 203, are different in their shapes. The red Micro-LED grain 201 can only match the first recess 1031 at a corresponding position, i.e., the red Micro-LED grain 201 can only fall into the first recess 1031 at a position corresponding to the red Micro-LED grain, and cannot fall into the second recess 1032 at a position corresponding to the green Micro-LED grain or the third recess 1033 at a position corresponding to the blue Micro-LED grain. Similarly, the green Micro-LED grain 202 can only match the second recess 1032 at a corresponding position, and the blue Micro-LED grain 203 can only match the third recess 1033 at a corresponding position.

In one embodiment, the above step 13 of forming solder on the first metal bonding pad of the transfer plate or the second metal bonding pad of the Micro-LED gain may include: placing the transfer plate or the Micro-LED gains into the solder in liquid state, thereby forming the solder on the first metal bonding pad of the transfer plate or the second metal bonding pad of the Micro-LED gain.

In other words, the transfer plate may be placed into the solder in liquid state, thereby forming the solder on the first metal bonding pad of the transfer plate; or, the Micro-LED gains may be placed into the solder in liquid state, thereby forming the solder on the second metal bonding pad of the Micro-LED gain. It should be understood that since the quantity of the Micro-LED gains is large, optionally, it is better to place the transfer plate into the solder in liquid state, thereby forming liquid-state solder on the first metal bonding pad of the transfer plate. In the embodiment shown in FIG. 2, the transfer plate is placed into the solder in liquid state, thereby forming the liquid-state solder 104 on the first metal bonding pad 102 of the transfer plate.

By placing the transfer plate or the Micro-LED gains into the solder in liquid state, it is ensured to form the solder on each metal bonding pad, thereby avoiding welding defects caused by absence of solder on some metal pads.

Of course, in some embodiments, other approaches such as spraying may be used to form the solder on the first metal bonding pad of the transfer plate or the second metal bonding pad of the Micro-LED gain.

In one embodiment, optionally, the solder may be a eutectic solder. The eutectic solder is an alloy composed of two or more metals, and its melting point is much lower than the melting point of any metal in the alloy. The eutectic solder is a low-temperature solder and has good solder-ability. Thus, welding properties of the micro-LED grains can be improved by using the eutectic solder.

In one embodiment, the chamber may be vibrated in many ways as illustrated by the following example.

In one embodiment, referring to FIG. 5, an electromagnet base station 500 is provided below the chamber 300, and the steps for vibrating the chamber 300 include: energizing an electromagnet 501 of the electromagnet base station 500 corresponding to a specified region of the transfer plate 100, and controlling the electromagnet base station 500 to vibrate, thereby vibrating the chamber 300 and then enabling the Micro-LED grains 200 to fall into recesses corresponding to the specified region under action of vibration and electromagnetic force. In one embodiment, the Micro-LED grains 200 fall into the recesses corresponding to the specified region under action of the vibration and the electromagnetic force.

In the above embodiment, the to-be-assembled Micro-LED grains may include N types of Micro-LED grains, where N is a positive integer greater than or equal to 2. Light rays emitted from the Micro-LED grains of different types have different colors.

In this case, the step of placing the transfer plate and the Micro-LED grains into the chamber and vibrating the chamber includes: a step 151 of placing the transfer plate into the chamber; and a step 152 of performing the following sub-steps 1521 to 1522 to each of the N types of the Micro-LED grains sequentially. The sub-step 1521 is to put one type of the Micro-LED grains into the chamber. The Micro-LED grains put into the chamber are corresponding to the recesses in the specified region of the transfer plate. The sub-step 1522 is to energize the electromagnet of the electromagnet base station corresponding to the specified region of the transfer plate and control the electromagnet base station to vibrate, thereby vibrating the chamber and then enabling the Micro-LED grains to fall into recesses corresponding to the specified region under action of vibration and electromagnetic force.

In one embodiment, optionally, the Micro-LED grains of different types have different shapes. Meanwhile, the recesses have N shapes which are corresponding to the N types of Micro-LED grains in a one-to-one manner. Thus, when assembling the Micro-LED grains, each of the Micro-LED grains can only be embedded in one recess of corresponding shape, thereby improving yield.

Further, the recess of each shape can only be adapted to the corresponding type of Micro-LED grain.

Optionally, the Micro-LED grains include 3 types of Micro-LED grains, which include red Micro-LED grains for emitting red light, green Micro-LED grains for emitting green light and blue Micro-LED grains for emitting blue light.

Referring to FIG. 5, when assembling the Micro-LED grains into the transfer plate, the transfer plate may be first placed into the chamber 300 which contains the solvent 400. Then, the red Micro-LED grains 201 are put into the chamber. It is needed to assemble the red Micro-LED grains 201 into the first recesses 1031 in the transfer plate 100. Then, the electromagnet 501 of the electromagnet base station 500 corresponding to a region of the first recesses 1031 (i.e., the above specified region) is energized, and the electromagnet base station 500 is controlled to vibrate, thereby vibrating the chamber 300 and then enabling the Micro-LED grains 201 put into the chamber 300 to fall into the first recesses 1031 under action of vibration and electromagnetic force. In this way, the assembly of the red Micro-LED grains 201 is completed. After that, the green Micro-LED grains and the blue Micro-LED grains are put into the chamber 300 sequentially, and then the assembly of the green Micro-LED grains and the blue Micro-LED grains is completed,

In the above embodiment, massive Micro-LED grains can be transferred by preparing the transfer plate, bonding via soldering at low temperature and the electromagnetic-and-vibration assembly, thereby achieving the purpose of massive transfer of micro-LED grains and bonding. The process is simple and the cost is low.

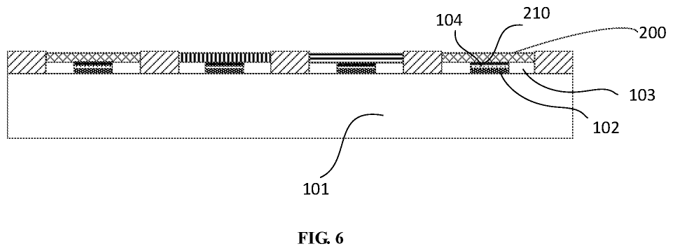

One embodiment of the present disclosure further provides a Micro-LED substrate which may be prepared according to the above method. As shown in FIG. 6, the Micro-LED substrate includes: a base substrate 101; a plurality of first metal bonding pads 102 on the base substrate 101; an insulation film on the base substrate 101 and provided with a plurality of recesses 103 for accommodating first metal bonding pads 102 therein; and a plurality of Micro-LED grains 200.

The Micro-LED gain 200 is provided with a second bonding metal 210 at a backside of the Micro-LED gain 200. The backside of the Micro-LED gain 200 and a light emitting side of the Micro-LED gain are two opposite sides of the Micro-LED gain. The Micro-LED grains are in the recesses. The first metal bonding pad is welded to the second metal bonding pad via the solder 104.

Optionally, the Micro-LED grains include N types of Micro-LED grains, where N is a positive integer greater than or equal to 2. Light rays emitted from the Micro-LED grains of different types have different colors.

Optionally, the Micro-LED grains of different types have different shapes. Meanwhile, the recesses have N shapes which are corresponding to the N types of Micro-LED grains in a one-to-one manner.

Optionally, the recess of each shape can only be adapted to the corresponding type of Micro-LED grain.

Optionally, the Micro-LED grains include 3 types of Micro-LED grains, which include red Micro-LED grains for emitting red light, green Micro-LED grains for emitting green light and blue Micro-LED grains for emitting blue light.

Unless otherwise defined, any technical or scientific terms used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than being limited to physical or mechanical connection. Such words as “on/above”, “under/below”, “left” and “right” are merely used to represent relative position relationship, and when an absolute position of an object is changed, the relative position relationship will be changed too.

The above are merely the optional embodiments of the present disclosure and shall not be used to limit the scope of the present disclosure. It should be noted that, a person skilled in the art may make improvements and modifications without departing from the principle of the present disclosure, and these improvements and modifications shall also fall within the scope of the present disclosure.

What is claimed is:

1. A method for transferring massive Micro-LED, comprising:
providing a transfer plate; wherein the transfer plate includes a base substrate, an insulation film on the base substrate and a plurality of first metal bonding pads on the base substrate, the insulation film is provided with a plurality of recesses for accommodating Micro-LED grains, and the first metal bonding pad is in the recess;
providing a plurality of Micro-LED grains; wherein the Micro-LED gain is provided with a second bonding metal at a backside of the Micro-LED gain, and the backside of the Micro-LED gain and a light emitting side of the Micro-LED gain are two opposite sides of the Micro-LED gain;
forming solder on the first metal bonding pad of the transfer plate or the second metal bonding pad of the Micro-LED gain;
placing the transfer plate and the Micro-LED gains into a chamber which contains solvent, vibrating the chamber to enable the Micro-LED gains to fall into the recesses of the transfer plate, thereby enabling the second metal bonding pads of the Micro-LED gains fallen in the recesses to be in contact with the first metal bonding pads in the recesses through the solder; wherein a temperature in the chamber is higher than a melting point of the solder; and
cooling down the transfer plate, thereby solidifying the solder and then forming a Micro-LED substrate.

2. The method of claim 1, wherein the cooling down the transfer plate includes:
removing the solvent from the chamber and cooling down the chamber; or
removing the transfer plate from the chamber and cooling down the transfer plate.

3. The method of claim 1, wherein the solvent is an organic solvent.

4. The method of claim 3, wherein a density of the organic solvent is less than a density threshold.

5. The method of claim 1, wherein the forming solder on the first metal bonding pad of the transfer plate or the second metal bonding pad of the Micro-LED gain, includes:
placing the transfer plate or the Micro-LED gains into liquid-state solder, thereby forming the solder on the first metal bonding pads of the transfer plate or the second metal bonding pads of the Micro-LED gains.

6. The method of claim 5, wherein the solder is a eutectic solder.

7. The method of claim 1, wherein an electromagnet base station is provided below the chamber;
the vibrating the chamber includes: energizing an electromagnet of the electromagnet base station corresponding to a specified region of the transfer plate, and controlling the electromagnet base station to vibrate, thereby vibrating the chamber and then enabling the Micro-LED grains to fall into the recesses corresponding to the specified region under action of vibration and electromagnetic force.

8. The method of claim 7, wherein the Micro-LED grains include N types of Micro-LED grains, wherein N is a positive integer greater than or equal to 2; light rays emitted from the Micro-LED grains of different types have different colors;
the placing the transfer plate and the Micro-LED gains into a chamber which contains solvent, vibrating the chamber, includes:
placing the transfer plate into the chamber; and
for each of the N types of the Micro-LED grains, performing following operations sequentially:
putting the Micro-LED grains of one type into the chamber, wherein the Micro-LED grains put into the chamber are corresponding to the recesses in the specified region of the transfer plate; and
energizing the electromagnet of the electromagnet base station corresponding to the specified region of the transfer plate and controlling the electromagnet base station to vibrate, thereby vibrating the chamber and then enabling the Micro-LED grains put into the chamber to fall into recesses corresponding to the specified region under action of vibration and electromagnetic force.

9. The method of claim 8, wherein the Micro-LED grains of different types have different shapes; and the recesses have N shapes which are corresponding to the N types of Micro-LED grains in a one-to-one manner.

10. The method of claim 9, wherein the recess of each shape matches only the Micro-LED grain of the corresponding type.

11. The method of claim 9, wherein the Micro-LED grains include 3 types of Micro-LED grains, which include red Micro-LED grains for emitting red light, green Micro-LED grains for emitting green light and blue Micro-LED grains for emitting blue light.

12. The method of claim 1, wherein the providing a transfer plate includes:
providing a base substrate;
forming a metal film on the base substrate;
patterning the metal film, thereby forming a plurality of first metal bonding pads;
forming an insulation film on the base substrate; and
patterning the insulation film, thereby forming a plurality of recesses in the insulation film;
wherein one of the first metal bonding pads is in one of the recesses.

13. The method of claim 12, wherein the insulation film is an organic film or a passivation film.

14. The method of claim 1, wherein the providing a plurality of Micro-LED grains includes:
providing a Micro-LED wafer;
forming a metal layer on a backside of the Micro-LED wafer; and
cutting the Micro-LED wafer to form a plurality of Micro-LED grains;
wherein one of the second metal bonding pads is provided at the backside of one Micro-LED grain.

15. The method of claim 14, wherein before the cutting the Micro-LED wafer to form a plurality of Micro-LED grains, the method further includes: patterning the metal layer, thereby forming a plurality of second metal bonding pads.

16. A Micro-LED substrate comprising:
a base substrate;
an insulation film on the base substrate and provided with a plurality of recesses;
a plurality of first metal bonding pads on the base substrate and in the plurality of recesses;
a plurality of Micro-LED grains in the plurality of recesses; wherein the Micro-LED gain is provided with a second bonding metal at a backside of the Micro-LED gain, the backside of the Micro-LED gain and a light emitting side of the Micro-LED gain are two opposite sides of the Micro-LED gain; and
wherein the first metal bonding pad is welded to the second metal bonding pad via a solder.

17. The Micro-LED substrate of claim 16, wherein the first metal bonding pads are in the recesses in a one-to-one manner.

18. The Micro-LED substrate of claim 17, wherein the first metal bonding pads are directly formed on the base substrate.

19. The Micro-LED substrate of claim 17, wherein the Micro-LED grains include N types of Micro-LED grains, where N is a positive integer greater than or equal to 2;
light rays emitted from the Micro-LED grains of different types have different colors; and
the Micro-LED grains of different types have different shapes; the recesses have N shapes which are corresponding to the N types of Micro-LED grains in a one-to-one manner.

20. The Micro-LED substrate of claim 19, wherein in a direction perpendicular to the base substrate, a thickness of the insulation film is equal to a sum of a thickness of the first metal bonding pad, a thickness of the second metal bonding pad, a thickness of the solder and a thickness of the Micro-LED grain.
